(19) United States
(12) Patent Application Publication
(10) Pub. No.: US 2026/0156752 A1
(43) Pub. Date: Jun. 4, 2026

(54) MECHANICAL STABILIZERS FOR PRINTED CIRCUIT BOARD ENCLOSURES

(71) Applicant: NVIDIA CORPORATION, Santa Clara, CA (US)

(72) Inventors: Xianpeng HUANG, Suzhou City, Jiangsu Province (CN); Qiang CHEN, Shenzhen, Guangdong (CN); Aaron Ka Hoo POON, San Marino, CA (US); Xin YANG, Shenzhen, Guangdong (CN)

(21) Appl. No.: 18/704,029

(22) PCT Filed: Apr. 7, 2024
(86) PCT No.: PCT/CN2024/086441

§ 371 Date: Apr. 23, 2024

(51) Int. Cl. H05K 1/181

(52) U.S. Cl. CPC H05K 1/181; H05K 2201/10189

(57) ABSTRACT

Various embodiments include a printed circuit board cover assembly comprising a cover layer that attaches to at least a portion of a printed circuit board layer, and a retention hook that extends from the cover layer and physically interfaces with at least a portion of a connection port. In various embodiments, a printed circuit board package comprises a printed circuit board layer, a cover layer that attaches to at least a portion of the printed circuit board layer, and a retention hook extending from the cover layer, the retention hook configured to physically interface with at least a portion of a connection port.

### BACKGROUND

### Field of the Various Embodiments

The various embodiments relate generally to computer systems and mechanical engineering and electronic circuits and, more specifically, to mechanical stabilizers for printed circuit board enclosures.

### Description of the Related Art

Computer systems typically include various printed circuit boards (PCBs) to which various electronic components are coupled or attached. For example, a desktop computer may include a motherboard and one or more additional expansion cards, such as a processor card, an adapter card, a peripheral card, or a network card. These additional expansion cards connect to the motherboard via one or more electrical connectors, such as a peripheral component interconnect (PCI) bus or a PCI Express (PCIe) bus, via a connector port. An expansion card, such as a PCIe card, typically includes a link through which signals between the electronic components coupled or attached to the expansion card and the electronic components coupled or attached to the motherboard can be transmitted. The links included in expansion cards can have varying lengths, normally ranging from one lane (x1) to sixteen lanes (x16). Generally speaking, links with greater lengths increase throughput between the electronic components coupled or attached to the expansion card and the electronic components coupled or attached to the motherboard relative to links with shorter lengths.

A given expansion card or other printed circuit board usually includes, in addition to a link, a separate mechanical stabilizer that physically interfaces with the latch of a connector port when the link is physically interfaced with the connector port. In many designs, the mechanical stabilizer is shaped as a retention hook that locks the expansion card to the connector port, thereby providing increased mechanical stability and reducing shock and vibration failure. However, the physical requirements associated with the links and the electronics components coupled or attached to expansion cards impose various constraints on the design and fabrication of certain types of expansion cards. For example, a high-speed graphics card may include a large number of lanes, sometimes up to sixteen lanes, to enable parallel processing operations to be offloaded efficiently from a central processing unit coupled to the motherboard and a graphic processing unit coupled to a graphics card. However, using a large number of lanes for the increases the size and increases the design complexity for the graphics card. In general, the combination of the larger link sizes and the mechanical stabilizers associated with some expansion cards results in in larger expansion card designs and larger expansion card enclosures that require more physical space within a computer system. Because of the space constraints associated with many computer systems, the range of computer systems that can accommodate larger expansion card designs and larger expansion card enclosures is limited.

To address the above issues, some conventional approaches reduce the lengths of expansion cards by either decreasing the length of the link used to connect the expansion card to the motherboard or removing the retention hook acting as the mechanical stabilizer. However, reducing the length of the link reduces the speed of the connection between the expansion card and the motherboard, which can decrease the overall performance of the computer system. Removing the retention hook can reduce overall mechanical stability and can expose the expansion card to shock and vibration failure. Other conventional approaches attempt to replace the retention hook with an offset or extender bracket to enable the expansion card to engage directly with the computer chassis that holds the motherboard. However, adding an extender bracket to an expansion card typically increases the overall complexity of the design and fabrication of the expansion card enclosure.

As the foregoing illustrates, what is needed in the art are more effective ways to reduce printed circuit board size while maintaining overall mechanical stability.

### SUMMARY

Various embodiments include a printed circuit board cover assembly comprising a cover layer that attaches to at least a portion of a printed circuit board layer, and a retention hook that extends from the cover layer and physically interfaces with at least a portion of a connection port.

In various embodiments, a printed circuit board package comprises a printed circuit board layer, a cover layer that attaches to at least a portion of the printed circuit board layer, and a retention hook extending from the cover layer, the retention hook configured to physically interface with at least a portion of a connection port.

At least one technical advantage of the disclosed design relative to the prior art is that, with the disclosed design, a printed circuit board can be reduced in length while maintaining mechanical stability when connected to a motherboard or other computer component. In particular, by including a retention hook on a separate cover layer, a printed circuit board assembly can physically interface with the connection port and latch of a motherboard or other computer component, thereby providing overall mechanical stability and protection against shocks and vibrations. Further, by including the retention hook on a separate cover layer, the printed circuit board layer can be shortened without shortening the length of the link used for communicating with the motherboard or requiring additional stabilizer brackets. By enabling the printed circuit board layer to be shorter in length, the disclosed design reduces the complexity associated with designing and fabricating the printed circuit board layer without substantially increasing the complexity of the cover layer, which allows smaller printed circuit board package form factors that can be included in a wider range of computer systems. These technical advantages provide one or more technological improvements over prior art approaches.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 is a schematic drawing illustrating a circuit board assembly, according to the prior art.

FIG. 2A illustrates a view of the retention hook of a circuit board assembly of FIG. 1 contacting a latch of a card connector port, according to the prior art.

FIG. 2B illustrates another view of the retention hook and latch of FIG. 2A, according to the prior art.

FIG. 3 illustrates a printed circuit board package that includes a retention hook integrated into a top printed circuit board cover layer, according to various embodiments;

FIG. 4 illustrates a printed circuit board package that includes a retention hook integrated into a bottom printed circuit board cover layer, according to various embodiments;

FIG. 5A illustrates a view of the retention hook of FIG. 4, according to various embodiments;

FIG. 5B illustrates a view of the retention hook of FIG. 4 contacting a latch of a card connector port, according to various embodiments;

FIG. 6 illustrates a view of the card connector port and the latch connecting to the retention hook of FIG. 4 and the connection link of the circuit board, according to various embodiments;

FIG. 7 is an illustration of a printed circuit board package that includes an attachable retention hook attached to a bottom printed circuit board cover layer, according to various embodiments;

FIG. 8 is an expanded illustration of the printed circuit board package that includes the attachable retention hook of FIG. 7 attached to the bottom printed circuit board cover layer, according to various embodiments; and

FIG. 9 is a block diagram of a computer system configured to implement one or more aspects of the various embodiments.

### DETAILED DESCRIPTION

In the following description, numerous specific details are set forth to provide a more thorough understanding of the various embodiments. However, it will be apparent to one skilled in the art that the inventive concepts may be practiced without one or more of these specific details.

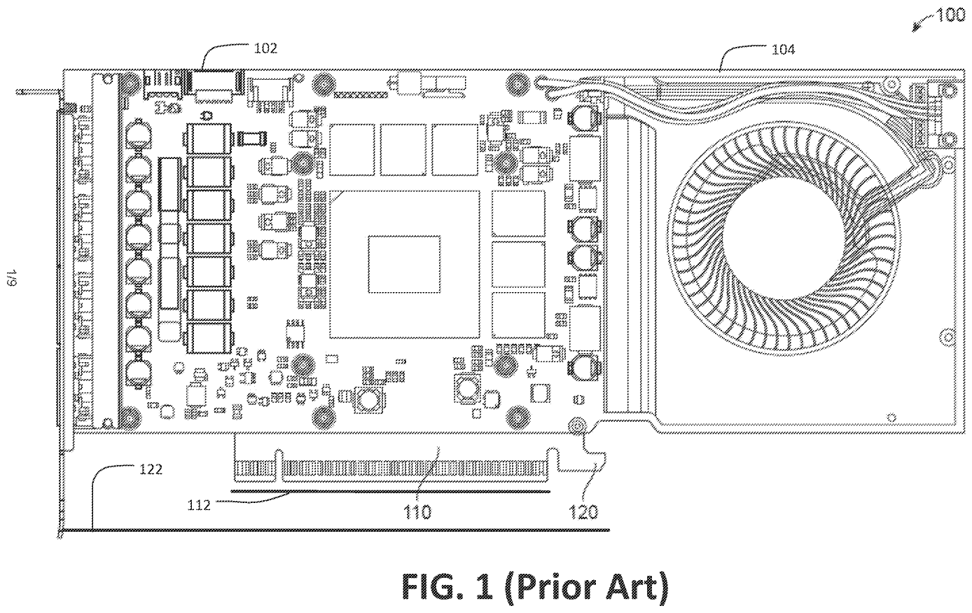

FIG. 1 is a schematic drawing illustrating a circuit board assembly 100, according to the prior art. As shown, the circuit board assembly 100 includes a printed circuit board 102 and a fan connection 104. The printed circuit board 102 includes a connection link 110 and a retention hook 120.

The printed circuit board assembly 100 can be an expansion card, such as a graphics card, which is configured to attach to another computer component via the connection link 110. As will be discussed in further detail below, the printed circuit board 102 further includes a retention hook 120 configured as mechanical stabilizer to physically engage with a portion of a connection port when the connection link 110 is mounted to the connection port.

In some examples, the printed circuit board assembly 100 adheres to one or more specifications and/or standards associated with computer hardware standards.

For example, the printed circuit board 102 adheres to the peripheral component interconnect express (PCIe) serial computer expansion bus standard that specifies an interface between motherboards and various expansion cards. In such instances, the connection link 110 has physical dimensions that adhere to the PCIe standard. For example, the connection link 110 includes up to sixteen lanes and has a length 112 that corresponds to physical dimensions specified by the PCIe standard (e.g., approximately 90 mm). The total length 122 of the printed circuit board 102 from a port endpoint to a connector endpoint (which connects to the fan connection 104) is based on the length 112 of the connection link 110 and the retention hook 120 (e.g., approximately 145 mm).

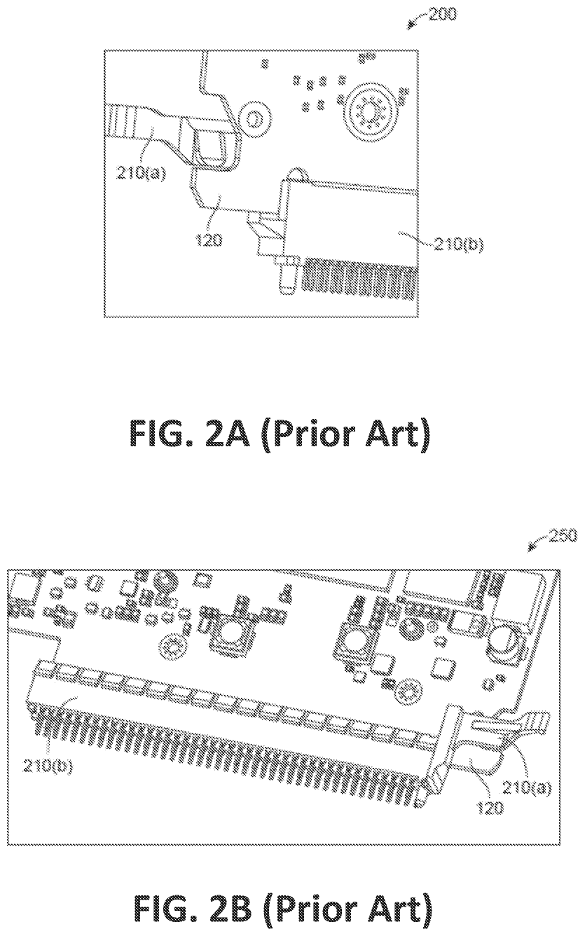

FIG. 2A illustrates a view 200 of the retention hook 120 of a circuit board assembly 100 of FIG. 1 contacting a latch 210(a) of a card connector port 210(b), according to the prior art. FIG. 2B illustrates another view 250 of the retention hook 120 and latch 210(a) of FIG. 2A, according to the prior art.

View 200 illustrates how the retention hook 120 physically connects to the latch 210(a) when connection link 110 of the printed circuit board 102 is mounted into the card connector port 210(b). In operation, the retention hook 120 acts as a mechanical stabilizer, as the shape of the retention hook 120 prevents the connection link 110 from detaching from the card connector port 210(b) and decreases the risk of shock or vibration failure. The physical arrangement of the retention hook 120 to the latch 210(a) physically affixes the printed circuit board 102 to a separate computer component (e.g., a motherboard) that includes the card connector port 210(b).

To accommodate the retention hook 120, the printed circuit board 102 of the prior art printed circuit board assembly 100 is constrained to have a minimum of length of at least the length 122. Such dimensions enable the retention hook 120 to properly physically interface with the latch 210(a) of the card connector port 210(b). As a result, the prior art printed circuit board assembly 100 is associated with high complexity in design, as the large sizes of the printed circuit boards 102 are difficult to design and/or fabricate. Further, the length 122 of the printed circuit board 102, due to the inclusion of both the connection link 110 and the retention hook 120, results in the printed circuit board assembly 100 having large physical dimensions relative to other computer components that limits where the printed circuit board assembly 100 can be included within a given computer chassis.

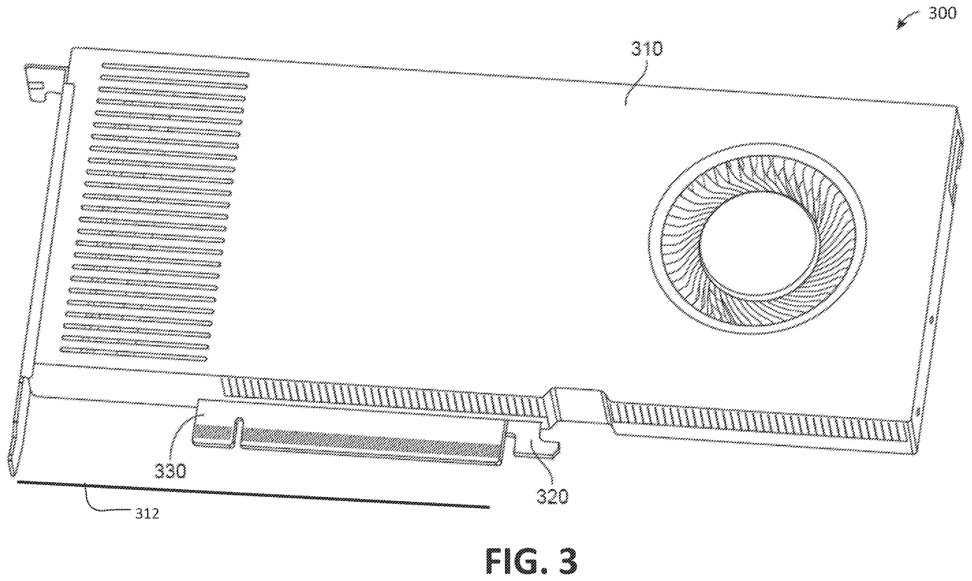

FIG. 3 illustrates a printed circuit board package 300 that includes a retention hook 320 integrated into a top printed circuit board cover layer 310, according to various embodiments. As shown, the printed circuit board package 300 includes, without limitation, a top printed circuit board cover layer 310, and a printed circuit board layer 330. The top printed circuit board cover layer 310 includes, without limitation, an integrated retention hook 320.

In various embodiments, the printed circuit board package 300 includes multiple layers, including a printed circuit board layer 330 and one or more cover layers. The one or more cover layers can include at least a top printed circuit board cover layer 310. In some embodiments, the one or more cover layers also includes a bottom printed circuit board layer (not shown).

In various embodiments, the top printed circuit board cover layer 310 is made of a rigid material, such as hard plastic (e.g., an injection molded plastic, computer numerical control (CNC) plastic, die cast plastic, etc.) or metal (e.g., aluminum, die cast metal, extruded metal, CNC metal, 3D printed metal, etc.). Additionally or alternatively, the top printed circuit board cover layer 310 can be die cast during fabrication. In some embodiments, the retention hook 320 is included in the die cast of the top printed circuit board cover layer 310. The retention hook 320 is configured to physically interface with the latch 210(a) of the card connector port 210(b) when the printed circuit board package 300 is mounted to the card connector port 210(b). In this manner, the retention hook 320 acts as a mechanical stabilizer in lieu of the retention hook 120 included in the prior art printed circuit board assembly 100. As a result, the printed circuit board layer 330 of the printed circuit board package 300 is shorter than the length 122 of the printed circuit board 102, as the length 312 (e.g., approximately 130 mm) of the printed circuit board layer 330 extends from the port endpoint to the end of the connection link.

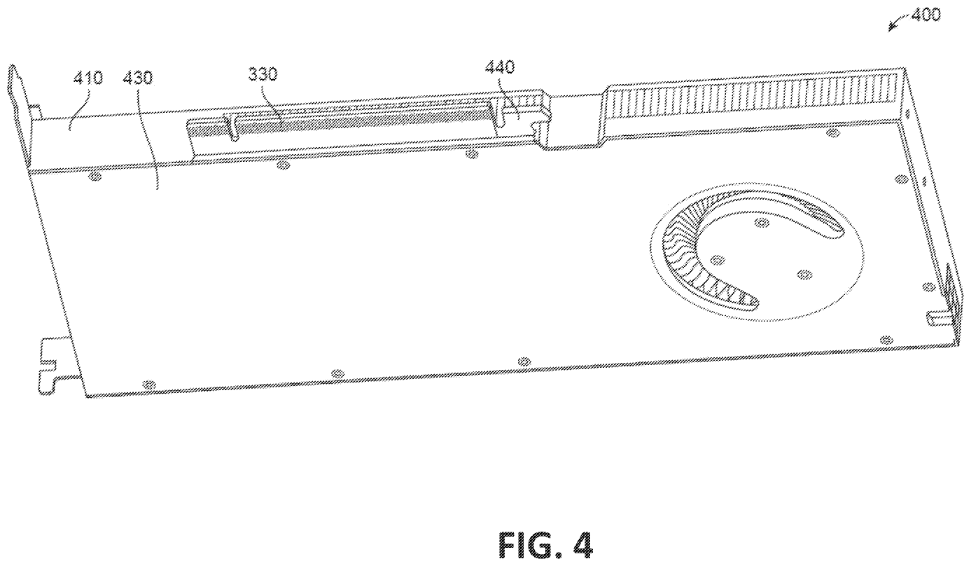

FIG. 4 illustrates a printed circuit board package 100 that includes a retention hook 440 integrated into a bottom printed circuit board cover layer 430, according to various embodiments. As shown, the printed circuit board package 400 includes, without limitation, a top printed circuit board cover layer 410, the printed circuit board layer 330, and the bottom printed circuit board cover layer 430. The bottom printed circuit board cover layer 430 includes, without limitation, an integrated retention hook 440. In various embodiments, the bottom printed circuit board cover layer 430 is made of a rigid material, such as hard plastic (e.g., an injection molded plastic, computer numerical control (CNC) plastic, die cast plastic, etc.) or metal (e.g., aluminum, die cast metal, extruded metal, CNC metal, 3D printed metal, etc.). In various embodiments, the bottom printed circuit board cover layer 430 can be made from a different material than the top printed circuit board cover layer 410.

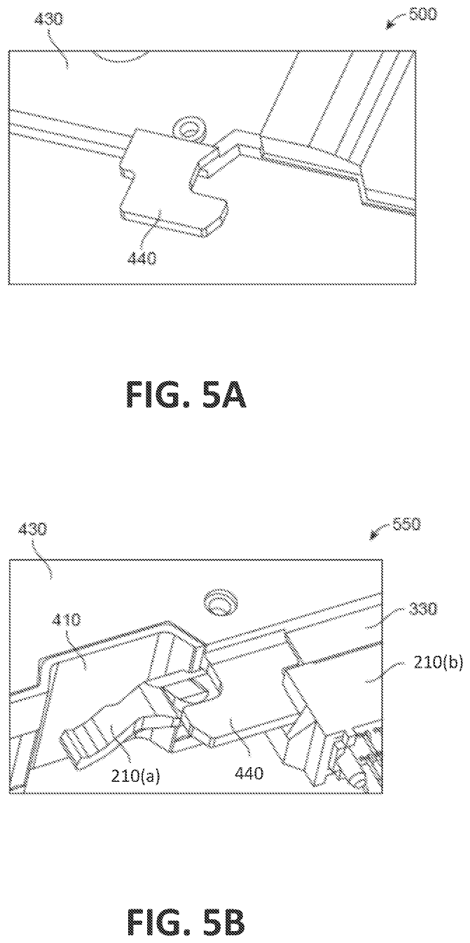

FIG. 5A illustrates a view 500 of the retention hook 440 of FIG. 4, according to various embodiments. In various embodiments, the bottom printed circuit board cover layer 430 can be die cast during fabrication. In some embodiments, the retention hook 440 is included in the die cast of the bottom printed circuit board cover layer 430. The retention hook 440 is configured to physically interface with the latch 210(a) of the card connector port 210(a) in lieu of the retention hook 120 included in the prior art printed circuit board assembly 100.

FIG. 5B illustrates a view 550 of the retention hook 440 of FIG. 4 contacting a latch 210(a) of a card connector port 210(b), according to various embodiments. View 550 illustrates how the retention hook 440 physically connects to the latch 210(a) when the printed circuit board package 300 is mounted into the card connector port 210(b). In operation, the retention hook 440 acts as a mechanical stabilizer in a similar manner to the retention hooks 120, 320. The shape of the retention hook 440 prevents the connection link 110 from detaching from the card connector port 210(b) and decreases the risk of shock or vibration failure. The physical arrangement of the retention hook 440 to the latch 210(a) physically affixes the printed circuit board 102 to a separate computer component (e.g., a motherboard) that includes the card connector port 210(b).

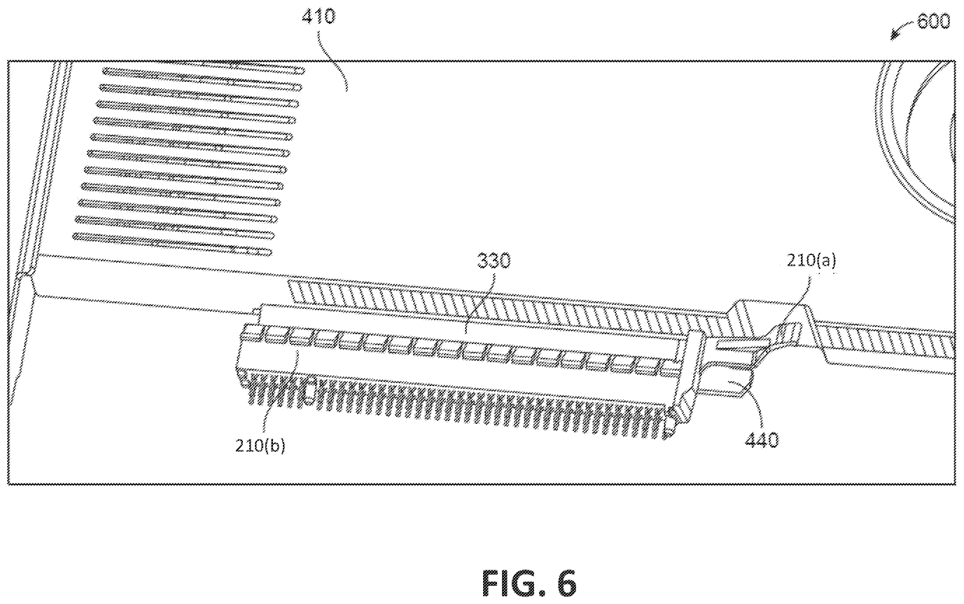

FIG. 6 illustrates a view 600 of the card connector port 210(b) and the latch 210(a) connecting to the retention hook 440 of FIG. 4 and the connection link of the circuit board 330, according to various embodiments. The retention hook 440 is configured to physically interface with the latch 210(a) of the card connector port 210(b) in lieu of the retention hook 120 included in the prior art printed circuit board assembly 100. As a result, the printed circuit board layer 330 of the printed circuit board package 400 can be shorter than the printed circuit board 102 while the retention hook 440 provides mechanical stability for the printed circuit board package 400.

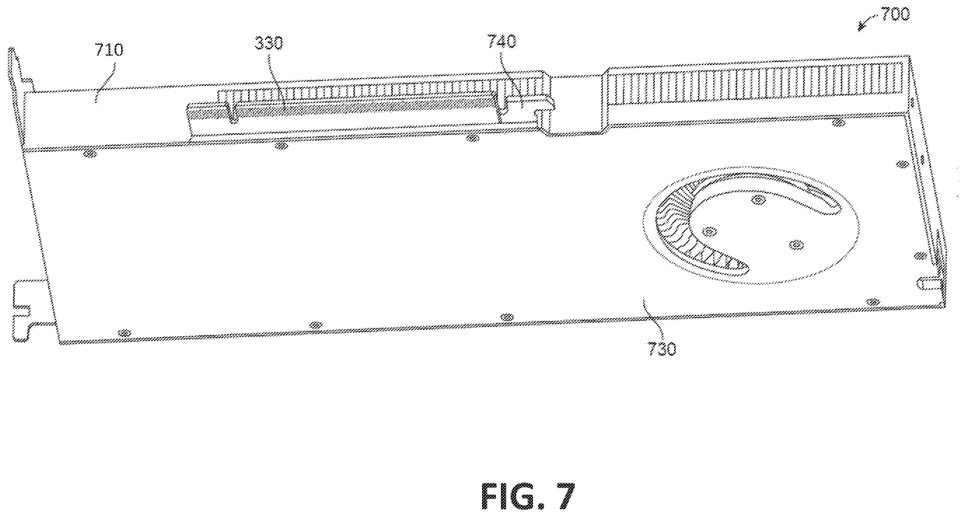

FIG. 7 is an illustration of a printed circuit board package 700 that includes an attachable retention hook 740 attached to a bottom printed circuit board cover layer, according to various embodiments. As shown, the printed circuit board package 700 includes, without limitation, a top printed circuit board cover layer 710, the printed circuit board layer 330, the bottom printed circuit board cover layer 730, and the retention hook 740. In various embodiments, the attachable retention hook 740 is made of a rigid material, such as hard plastic (e.g., an injection molded plastic, computer numerical control (CNC) plastic, die cast plastic, etc.) or metal (e.g., aluminum, die cast metal, extruded metal, CNC metal, 3D printed metal, etc.). In various embodiments, the retention hook 740 can be attached to either the top printed circuit board cover layer 710 or the bottom printed circuit board cover layer 730 via an attachment means, such as screws, epoxy, or other mechanical or chemical attachments known to persons skilled in the art.

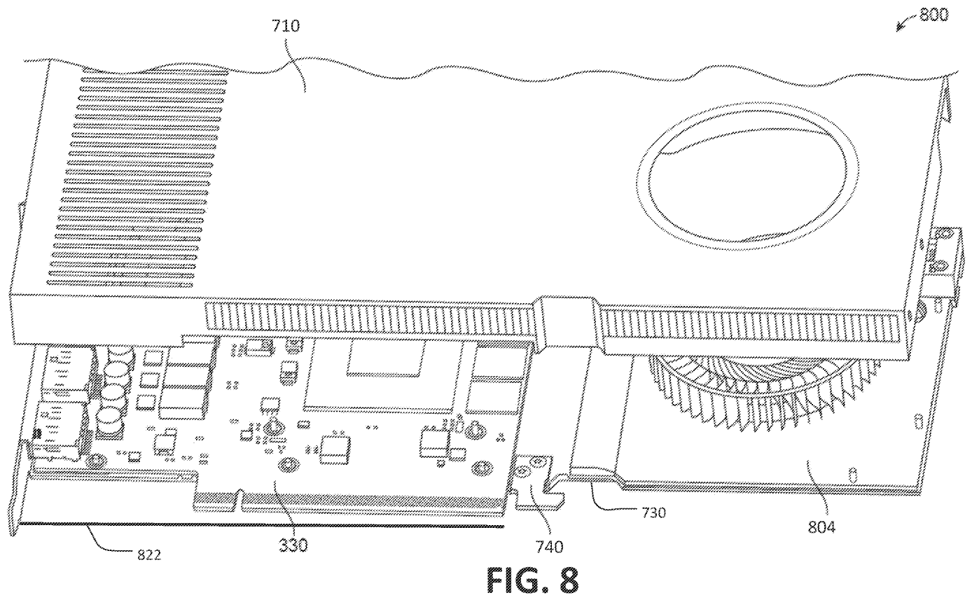

FIG. 8 is an expanded illustration of the printed circuit board package that includes the attachable retention hook 740 of FIG. 7 attached to the bottom printed circuit board cover layer 730, according to various embodiments. As shown, the printed circuit board package 800 includes, without limitation, the top printed circuit board cover layer 710, the bottom printed circuit board cover layer 730, the attachable retention hook 740, the printed circuit board layer 330, and a fan connection 804.

In various embodiments, the attachable retention hook 740 is configured to be attached to either the top printed circuit board cover layer 710 or the bottom printed circuit board cover layer 730 at a location proximate to the connection link of the printed circuit board layer 330. When attached at this location, the attachable retention hook 740 is configured to physically interface with the latch 210(a) of the card connector port 210(b) in lieu of the retention hook 120 included in the prior art printed circuit board assembly 100. As a result, the printed circuit board layer 330 of the printed circuit board package 800 is shorter than the length 122 of the printed circuit board 102, as the length 822 (e.g., approximately 130 mm) of the printed circuit board layer 330 extends from the port endpoint to the end of the connection link.

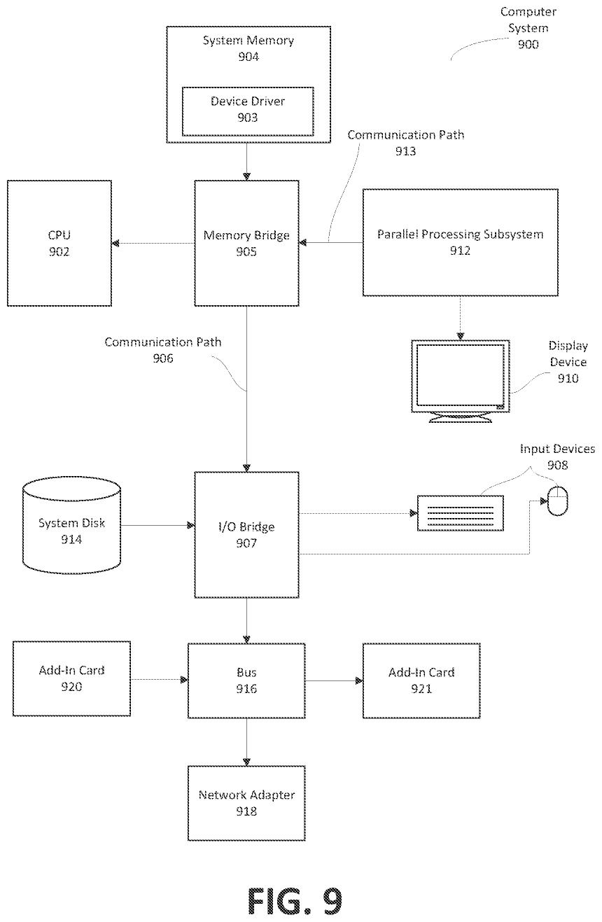

FIG. 9 is a block diagram of a computer system 900 configured to implement one or more aspects of the various embodiments. As shown, computer system 900 includes, without limitation, a central processing unit (CPU) 902 and a system memory 904 coupled to a parallel processing subsystem 912 via a memory bridge 905 and a communication path 913. Memory bridge 905 is further coupled to an I/O (input/output) bridge 907 via a communication path 906, and I/O bridge 907 is, in turn, coupled to a bus 916.

In various embodiments, one or more components of the computer system 900 (e.g., the CPU 902, the parallel processing subsystem 912, etc.) are included in one or more printed circuit board packages 300, 400, 700, 800. For example, the CPU 902, the parallel processing subsystem 912, the add-in cards 920, 921, and/or the network adapter can be included in one or more circuit board printed packages 300, 400, 700, 800.

In operation, I/O bridge 907 is configured to receive user input information from input devices 908, such as a keyboard or a mouse, and forward the input information to CPU 902 for processing via communication path 906 and memory bridge 905. Bus 916 is configured to provide connections between I/O bridge 907 and other components of the computer system 900, such as a network adapter 918 and various add-in cards 920 and 921.

As also shown, I/O bridge 907 is coupled to a system disk 914 that may be configured to store content and applications and data for use by CPU 902 and parallel processing subsystem 912. As a general matter, system disk 914 provides non-volatile storage for applications and data and may include fixed or removable hard disk drives, flash memory devices, and CD-ROM (compact disc read-only-memory), DVD-ROM (digital versatile disc-ROM), Blu-ray, HD-DVD (high-definition DVD), or other magnetic, optical, or solid-state storage devices. Finally, although not explicitly shown, other components, such as universal serial bus or other port connections, compact disc drives, digital versatile disc drives, film recording devices, and the like, may be connected to I/O bridge 907 as well.

In various embodiments, memory bridge 905 may be a Northbridge chip, and I/O bridge 907 may be a Southbrige chip. In addition, communication paths 906 and 913, as well as other communication paths within computer system 900, may be implemented using any technically suitable protocols, including, without limitation, AGP (Accelerated Graphics Port), HyperTransport, or any other bus or point-to-point communication protocol known in the art.

In some embodiments, parallel processing subsystem 912 comprises a graphics subsystem that delivers pixels to a display device 910 that may be any conventional cathode ray tube, liquid crystal display, light-emitting diode display, or the like. In such embodiments, the parallel processing subsystem 912 incorporates circuitry optimized for graphics and video processing, including, for example, video output circuitry. Such circuitry may be incorporated across one or more parallel processing units (PPUs) included within parallel processing subsystem 912. In other embodiments, the parallel processing subsystem 912 incorporates circuitry optimized for general purpose and/or compute processing. Again, such circuitry may be incorporated across one or more PPUs included within parallel processing subsystem 912 that are configured to perform such general purpose and/or compute operations. In yet other embodiments, the one or more PPUs included within parallel processing subsystem 912 may be configured to perform graphics processing, general purpose processing, and compute processing operations. System memory 904 includes at least one device driver 903 configured to manage the processing operations of the one or more PPUs within parallel processing subsystem 912. The system memory 904 also includes any number of software applications 625 that execute on the CPU 902 and may issue commands that control the operation of the PPUs.

In various embodiments, parallel processing subsystem 912 may be integrated with one or more other the other elements of FIG. 9 to form a single system. For example, parallel processing subsystem 912 may be integrated with CPU 902 and other connection circuitry on a single chip to form a system on chip (SoC).

It will be appreciated that the system shown herein is illustrative and that variations and modifications are possible. The connection topology, including the number and arrangement of bridges, the number of CPUs 902, and the number of parallel processing subsystems 912, may be modified as desired. For example, in some embodiments, system memory 904 could be connected to CPU 902 directly rather than through memory bridge 905, and other devices would communicate with system memory 904 via memory bridge 905 and CPU 902. In other alternative topologies, parallel processing subsystem 912 may be connected to I/O bridge 907 or directly to CPU 902, rather than to memory bridge 905. In still other embodiments, I/O bridge 907 and memory bridge 905 may be integrated into a single chip instead of existing as one or more discrete devices. Lastly, in certain embodiments, one or more components shown in FIG. 6 may not be present. For example, bus 916 could be eliminated, and network adapter 918 and add-in cards 920, 921 would connect directly to I/O bridge 907.

In sum, a printed circuit board assembly includes a printed circuit board layer and one or more cover layers. In various embodiments, the printed circuit board is an expansion card that includes a connection link, such as a PCI express link that includes sixteen lanes. The connection link is configured to physical contact a connection port on a separate component, such as a motherboard. At least one of the cover layers includes a retention hook. In some embodiments, the retention hook die cast with one or more other portions of the cover layer. Alternatively, in some embodiments, the retention hook is separably attached to the cover layer. The retention hook is arranged on the same side as the connection link and is configured to physically interface with a connection latch included in the connection port on the separate component.

When the printed circuit board assembly is mounted to a separate component via the connection port for operation of a computer device, the connection link physically contacts the connection port, and a connection latch physically contacts the retention hook such that the physical circuit board assembly is securely attached to the connection port. The retention hook included in the cover layer holds the printed circuit board layer in place in a manner that reduces the likelihood of shock or vibration failure during operation of the computer device.

At least one technical advantage of the disclosed design relative to the prior art is that, with the disclosed design, a printed circuit board can be reduced in length while maintaining mechanical stability when connected to a motherboard or other computer component. In particular, by including a retention hook on a separate cover layer, a printed circuit board assembly can physically interface with the connection port and latch of a motherboard or other computer component, thereby providing overall mechanical stability and protection against shocks and vibrations. Further, by including the retention hook on a separate cover layer, the printed circuit board layer can be shortened without shortening the length of the link used for communicating with the motherboard or requiring additional stabilizer brackets. By enabling the printed circuit board layer to be shorter in length, the disclosed design reduces the complexity associated with designing and fabricating the printed circuit board layer without substantially increasing the complexity of the cover layer, which allows smaller printed circuit board package form factors that can be included in a wider range of computer systems. These technical advantages provide one or more technological improvements over prior art approaches.

1. In various embodiments, a printed circuit board cover assembly comprises a cover layer that attaches to at least a portion of a printed circuit board layer, and a retention hook that extends from the cover layer and physically interfaces with at least a portion of a connection port.

2. The printed circuit board cover assembly of clause 1, where the retention hook physically interfaces with a latch associated with the connection port.

3. The printed circuit board cover assembly of clause 1 or 2, where the cover layer comprises a top cover layer that attaches to a top of the printed circuit board layer.

4. The printed circuit board cover assembly of any of clauses 1-3, where the cover layer comprises a bottom cover layer that attaches to a top of the printed circuit board layer.

5. The printed circuit board cover layer of any of clauses 1-4, where the retention hook is integrated with the cover layer.

6. The printed circuit board cover layer of any of clauses 1-5, where the cover layer and the retention hook are die cast during fabrication.

7. The printed circuit board cover layer of any of clauses 1-6, further comprising means for attaching the retention hook to the cover layer.

8. The printed circuit board cover layer of any of clauses 1-7, where the cover layer and the retention hook are fabricated from different materials.

9. In various embodiments, a printed circuit board package comprises a printed circuit board layer, a cover layer that attaches to at least a portion of the printed circuit board layer, and a retention hook extending from the cover layer, the retention hook configured to physically interface with at least a portion of a connection port.

10. The printed circuit board package of clause 9, where the printed circuit board layer has a length that is less than 140 mm.

11. The printed circuit board package of clause 9 or 10, where the printed circuit board layer has a length that is less than 130 mm.

12. The printed circuit board package of any of clauses 9-11, where the retention hook physically interfaces with a latch included in the connection port.

13. The printed circuit board package of any of clauses 9-12, where the cover layer comprises a top cover layer configured to attach to a top of the printed circuit board layer.

14. The printed circuit board package of any of clauses 9-13, where the cover layer comprises a bottom cover layer configured to attach to a top of the printed circuit board layer.

15. The printed circuit board package of any of clauses 9-12, wherein the retention hook is integrated with the cover layer.

16. The printed circuit board package of any of clauses 9-15, where the cover layer and the retention hook are die cast during fabrication.

17. The printed circuit board package of any of clauses 9-16, further comprising means for attaching the retention hook to the cover layer.

18. The printed circuit board package of any of clauses 9-17, where the cover layer and the retention hook are fabricated from different materials.

19. The printed circuit board package of any of clauses 9-18, where the printed circuit board layer further comprises a connection link configured to mount onto the connection port; and the retention hook is located proximate to the connection link.

20. The printed circuit board package of any of clauses 9-19, where the connection link has a length of at least 75 mm.

Any and all combinations of any of the claim elements recited in any of the claims and/or any elements described in this application, in any fashion, fall within the contemplated scope of the present invention and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

While the preceding is directed to embodiments of the present disclosure, other and further embodiments of the disclosure may be devised without departing from the basic scope thereof, and the scope thereof is determined by the claims that follow.

What is claimed is:

1. A printed circuit board cover assembly comprising:
a cover layer that attaches to at least a portion of a printed circuit board layer; and
a retention hook that extends from the cover layer and physically interfaces with at least a portion of a connection port.

2. The printed circuit board cover assembly of claim 1, wherein the retention hook physically interfaces with a latch associated with the connection port.

3. The printed circuit board cover assembly of claim 1, wherein the cover layer comprises a top cover layer that attaches to a top of the printed circuit board layer.

4. The printed circuit board cover assembly of claim 1, wherein the cover layer comprises a bottom cover layer that attaches to a top of the printed circuit board layer.

5. The printed circuit board cover assembly of claim 1, wherein the retention hook is integrated with the cover layer.

6. The printed circuit board cover assembly of claim 5, wherein the cover layer and the retention hook are die cast during fabrication.

7. The printed circuit board cover assembly of claim 1, further comprising means for attaching the retention hook to the cover layer.

8. The printed circuit board cover assembly of claim 1, wherein the cover layer and the retention hook are fabricated from different materials.

9. A printed circuit board package, comprising:
a printed circuit board layer;
a cover layer that attaches to at least a portion of the printed circuit board layer; and
a retention hook extending from the cover layer, the retention hook configured to physically interface with at least a portion of a connection port.

10. The printed circuit board package of claim 9, wherein the printed circuit board layer has a length that is less than 140 mm.

11. The printed circuit board package of claim 9, wherein the printed circuit board layer has a length that is less than 130 mm.

12. The printed circuit board package of claim 9, wherein the retention hook physically interfaces with a latch included in the connection port.

13. The printed circuit board package of claim 9, wherein the cover layer comprises a top cover layer configured to attach to a top of the printed circuit board layer.

14. The printed circuit board package of claim 9, wherein the cover layer comprises a bottom cover layer configured to attach to a top of the printed circuit board layer.

15. The printed circuit board package of claim 9, wherein the retention hook is integrated with the cover layer.

16. The printed circuit board package of claim 15, wherein the cover layer and the retention hook are die cast during fabrication.

17. The printed circuit board package of claim 9, further comprising means for attaching the retention hook to the cover layer.

18. The printed circuit board package of claim 9, wherein the cover layer and the retention hook are fabricated from different materials.

19. The printed circuit board package of claim 9, wherein:
the printed circuit board layer further comprises a connection link configured to mount onto the connection port; and
the retention hook is located proximate to the connection link.

20. The printed circuit board package of claim 19, wherein the connection link has a length of at least 75 mm.
